(19) United States
(12) Patent Application Publication
(10) Pub. No.: US 2002/0043695 A1
(43) Pub. Date: Apr. 18, 2002

(54) Method for forming an ultra thin dielectric film and a semiconductor device incorporating the same

(76) Inventors: Vishnu Agarwal, Boise, ID (US); Garry A. Mercaldi, Meridian, ID (US)

Correspondence Address: Killworth, Gottman, Hagan & Schaeff, L.L.P., Suite 500, One Dayton Centre, Dayton, OH, 45402-2023, US

(21) Appl. No.: 09/907,350

(22) Filed: Jul. 17, 2001

Related U.S. Application Data
(62) Division of application No. 09/689,409, filed on Oct. 12, 2000.

(51) Int. Cl. H01L 31/0232

(52) U.S. Cl. 257/435

(57) ABSTRACT

A method of forming an ultra thin dielectric film or dielectric layer on a semiconductor device is disclosed. In one embodiment of the present invention, an oxide layer is formed over a substrate. A silicon-containing material is deposited over the oxide layer. The deposited material and oxide layer are processed in a plasma to form the dielectric layer or ultra thin dielectric film. The silicon-containing dielectric layer can allow for improved or smaller semiconductor devices. The silicon containing dielectric layer can be fabricated at low temperatures. Improved or smaller semiconductor devices may be accomplished by reducing leakage, increasing the dielectric constant or fabricating at lower temperatures.

### CROSS-REFERENCES TO RELATED APPLICATIONS

This application is related to commonly assigned U.S. patent application Ser. No. 09/653,639 (Attorney Docket No. MIO0059PA), METHOD FOR FORMING A BARRIER LAYER AND A SEMICONDUCTOR DEVICE INCORPORATING THE SAME, filed Aug. 31, 2000, by Powell et al. and Ser. No. 09/653,096 (Attorney Docket No. MIO0060PA, METHOD FOR FORMING A DIELECTRIC LAYER AND A SEMICONDUCTOR DEVICE INCORPORATING THE SAME, filed Aug. 31, 2000, by Powell et al., the disclosures of which are incorporated herein by reference.

### FIELD OF THE INVENTION

The present invention relates to the field of semiconductors and, more particularly, to forming a dielectric layer at a low temperature.

### BACKGROUND OF THE INVENTION

There is an increasing demand for semiconductor devices of reduced size. The performance characteristics of semiconductor devices become more important as device size decreases. Accordingly, processes that enhance performance characteristics are important to improved semiconductor fabrication. For example, capacitor performance can be improved by improving the dielectric constant of the capacitor's dielectric layer and reducing leakage across the dielectric layer.

Ultra thin dielectric films can greatly affect the performance of semiconductor devices. Ultra thin films are normally used as dielectric layers in semiconductor devices. Conventional ultra thin films and dielectric fabrication methods require high temperatures and are often inadequate to allow significant reduction of semiconductor device size.

Accordingly, there is a need in the art for an improved method of forming a dielectric layer or ultra thin dielectric film.

### SUMMARY OF THE INVENTION

This need is met by the present invention wherein a method of forming an ultra thin dielectric film or dielectric layer on a semiconductor device is disclosed. According to one embodiment of the present invention, a semiconductor device is provided. An oxide layer is formed over the semiconductor device. A silicon-containing material is deposited over at least a portion of the oxide layer. The oxide layer and deposited silicon-containing material are converted to the ultra thin dielectric film by processing the deposited silicon-containing material and the oxide layer in a high density plasma.

According to another embodiment of the present invention, a method of forming a dielectric layer on a semiconductor device is disclosed. A semiconductor device having an oxide layer is provided. A silicon-containing material is vapor deposited over at least a portion of the semiconductor device. The deposited silicon-containing material and the oxide layer are converted into the dielectric layer by utilizing a high density plasma.

According to another embodiment of the present invention a semiconductor device is disclosed. The semiconductor device includes a substrate and a dielectric layer. The dielectric layer is formed over the substrate by converting vapor deposited silicon-containing material and a thin oxide layer using a high density plasma.

Other methods and devices are disclosed.

### BRIEF DESCRIPTION OF THE SEVERAL VIEWS OF THE DRAWINGS

The following detailed description of the present invention can be best understood when read in conjunction with the accompanying drawings, where like structure is indicated with like reference numerals.

FIG. 1 illustrates a method for forming a dielectric layer according to one embodiment of the present invention.

FIGS. 2A, 2B and 2C illustrate a semiconductor device with a nitrided gate and its method of fabrication according to another embodiment of the present invention.

FIGS. 3A, 3B and 3C illustrate a semiconductor device and its method of fabrication according to another embodiment of the present invention.

FIGS. 4A, 4B and 4C illustrate a semiconductor device and its method of fabrication according to another embodiment of the present invention.

FIG. 5 illustrates a computer system that can use and be used with embodiments of the present invention.

### DETAILED DESCRIPTION OF THE INVENTION

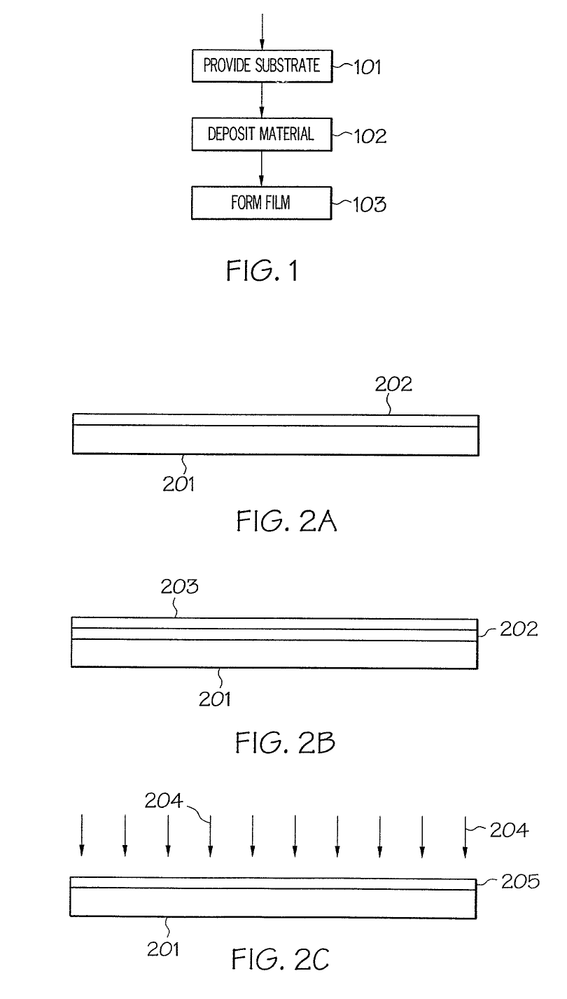

FIG. 1 illustrates a method for forming a dielectric layer or ultra thin dielectric film according to one embodiment of the present invention. A substrate is provided at block 101. The substrate may comprise one or more semiconductor layers or semiconductor structures which may define portions of a semiconductor device. A semiconductor device may comprise a transistor, capacitor, electrode, insulator or any of a variety of components commonly utilized in semiconductor structures. A silicon-containing material is vapor deposited over the substrate from a silicon source at block 102. As is noted below, the silicon-containing material can be from a silazane or silane source such as hexamethyldisilazane (HMDS).

The dielectric layer or ultra thin dielectric film is formed by subjecting the deposited silicon-containing material to a high density plasma at a low temperature at block 103. For the present invention, a low temperature is defined as a temperature less than 300° C. A “high density plasma” is a plasma containing a higher density of ions in comparison to a normal plasma. Normal plasma has an ion concentration in the range of 10⁹ ions/cm³ whereas high density plasma generally has a ion concentration of 10¹¹ to 10¹² ions/cm³ (1000 times higher compared to normal plasma). Silicon atoms of the deposited material react with ions of the high density plasma. The high density plasma contains H₂, NH₃, N₂, O₂, O₃, N₂O or NO which are converted to ions or activated species by the high density plasma.

During the process of subjecting the deposited silicon-containing material to a high density plasma, the plasma can be remote or in contact with the wafer. The resulting film can be a nitride, oxynitride or oxide film with specific electrical properties, depending on the type of high density plasma used. Some examples of silicon-containing sources which may be used are hexamethyldisilazane (HMDS), tetramethyldisilazane, octamethylcyclotetrasilazine, hexamethylcyclotrisilazine, diethylaminotrimethylsilane and dimethylaminotrimethylsilane, however other silicon-containing sources may be used.

According to the remote plasma process of the present invention, the plasma is generated with microwaves or another form of conventional plasma generating energy. Specifically, a wafer or substrate is placed in a chamber. Gases such as H₂, NH₃, N₂, O₂, O₃, N₂O and NO are exposed to plasma generated outside of the chamber to create the activated species, such as H₂, NH₃, N₂, O₂, O₃, N₂O or NO ions. The plasma does not come into physical contact with the wafer or surface of the substrate which, in this case, is the silicon-containing material. The activated species are subsequently pumped into the chamber. This can reduce or prevent damage to the substrate or device.

Suitable remote plasma process parameters for a microwave plasma source include a power source of 500 W to 5 KW, a gas flow rate of 0-5000 cm³/min and a pressure of 100 mT to 50 T.

The contact plasma process is also referred to as a direct plasma process. The wafer containing the semiconductor device is placed in a chamber and the high density plasma is generated in the chamber, creating activated species. The plasma comes into direct contact with the wafer. Exemplary parameters include a power source of 100 W to 4 kW, gas flow rate of 0-5000 cm³/min and a chamber pressure of 500 mT to 5 T.

FIGS. 2A, 2B and 2C illustrate a semiconductor device with a nitrided gate according to another embodiment of the present invention. FIG. 2A shows the semiconductor device having a substrate 201 and a gate oxide 202 prior to depositing a silicon-containing material from a silicon source such as HMDS. The substrate 201 is of a semiconductor material such as, but not limited to silicon. The gate oxide 202 is formed over the substrate 201. FIG. 2B shows the semiconductor device having the substrate 201, the gate oxide 202 and a silicon containing material 203, after depositing the the silicon containing material 203. The silicon containing material 203 has been vapor deposited over the gate oxide 202. FIG. 2C shows the semiconductor device after the silicon containing material 203 has been subjected to high density plasma (HDP) 204 and includes the substrate 201 and an oxynitrided gate 205. The silicon containing material 203 can be subjected to the HDP remotely or directly. The gate oxide 202 and the silicon containing material 203 have been converted into the oxynitrided gate 205 by the HDP 204. The HDP 204 can include any activated species of plasma that converts the silicon containing material 203 and gate oxide 202 into the oxynitrided gate 205. Some examples of precursors used in such plasmas for nitridation are NH₃, N₂, and N₂+H₂. The oxynitrided gate 205 has a thickness of less than 30 Å and is comprised of Si₃N₄ or SiOₓN_{y}.

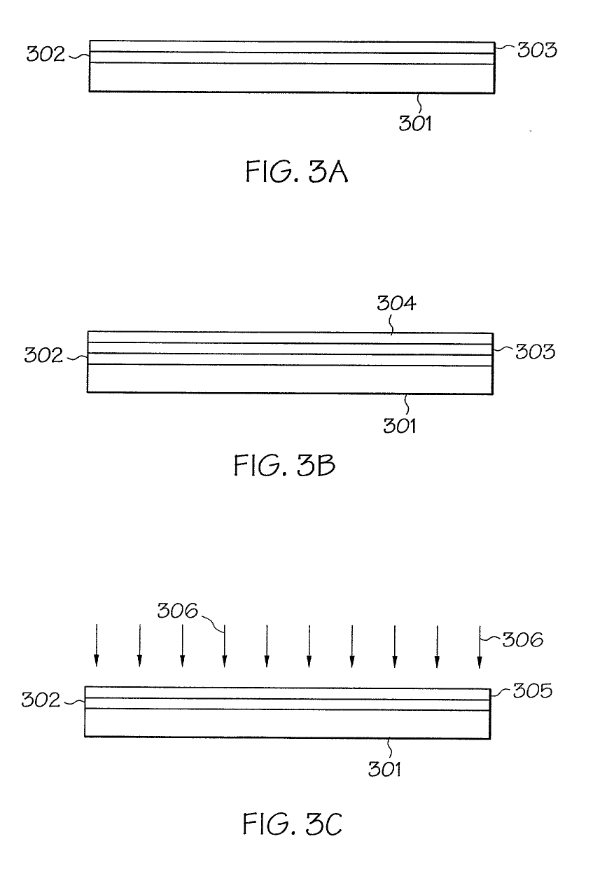

FIGS. 3A, 3B and 3C illustrate a semiconductor device according to another embodiment of the present invention. FIG. 3A shows the semiconductor device having a substrate 301, a lower electrode 302 and a native oxide 303 prior to depositing a silicon layer 304. The substrate 301 is of a semiconductor material such as, but not limited to silicon. The lower electrode 302 is formed over the substrate 301. Typically, the native oxide 303 is formed over the lower electrode 302. The native oxide 303 naturally occurs on the lower electrode 302. In other embodiments, an oxide layer can be grown or deposited instead of using a native oxide layer. FIG. 3B shows the semiconductor device having the substrate 301, the lower electrode 302, the native oxide 303 and a silicon layer 304. The silicon layer 304 is typically vapor deposited over the native oxide 303 from a silicon source such as HMDS. FIG. 3C shows the semiconductor device after the silicon layer 304 has been subjected to HDP 306 and includes the substrate 301, the lower electrode 302 and a dielectric layer 305. The silicon layer 304 can be subjected to the HDP 306 remotely or directly. The native oxide 303 and the silicon layer 304 are converted into the oxynitrided gate 305 by the HDP 306 by causing silicon atoms of the silicon layer 304 to react with the native oxide and ions in the HDP 306. The HDP 306 can include any activated species of plasma that converts the silicon layer 304 and gate oxide 303 into the dielectric layer 305. Some examples of such plasmas are NH₃, N₂, and N₂+H₂. The dielectric layer 305 has a thickness of less than 30 Å.

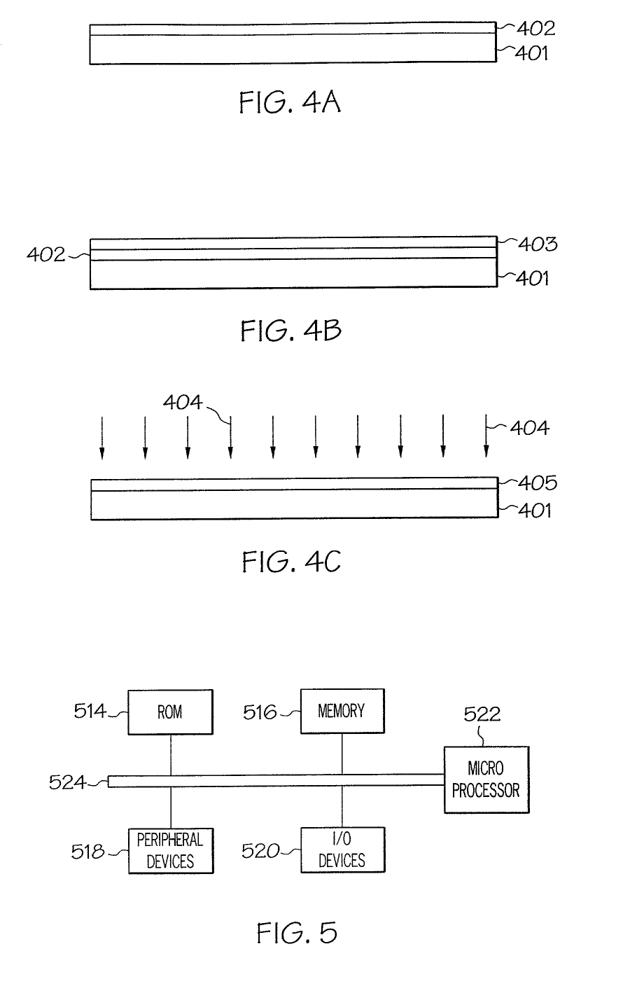

FIGS. 4A, 4B and 4C illustrate a semiconductor device according to another embodiment of the present invention. FIG. 4A shows the semiconductor device having a substrate 401 and an oxide 402 prior to depositing a silicon-containing layer. The substrate 401 is of a semiconductor material such as, but not limited to silicon. The oxide 402 is formed over the substrate 401. FIG. 4B shows the semiconductor device having the substrate 401, the oxide 402 and a silicon-containing layer 403, after depositing the silicon-containing layer 403. The silicon-containing layer 403 is typically vapor deposited over the oxide 402. FIG. 4C shows the semiconductor device after the silicon containing layer 403 has been subjected to HDP 404 and includes the substrate 401 and a dielectric layer 405. The semiconductor device can be subjected to the HDP remotely or directly. The oxide 402 and silicon-containing layer 403 are converted into the dielectric layer 405 by the plasma 404. The plasma 404 can include any activated species of plasma that converts the silicon-containing layer 403 and oxide 402 into the dielectric layer 405. Some examples of such plasmas are NH₃, N₂, and N₂+H₂. The dielectric layer 405 can have a thickness of less than 30 Å.

FIG. 5 is an illustration of a computer system 512 that can use and be used with embodiments of the present invention. As will be appreciated by those skilled in the art, the computer system 512 would include ROM 514, mass memory 516, peripheral devices 518, and I/O devices 520 in communication with a microprocessor 522 via a data bus 524 or another suitable data communication path. These devices can be fabricated according to the various embodiments of the present invention. For example, mass memory 516 can comprise memory cells having at least one ultra thin dielectric film formed according to one embodiment of the invention.

Dielectric layers or ultra thin dielectric films fabricated using the present invention can be used for a variety of purposes. Some examples follow, but embodiments of the present invention are not limited to these. A dielectric layer can be used as a cell dielectric material. A dielectric layer can be used as a single dielectric in a capacitor, transistor or anti-fuse application. A dielectric layer can be used to form composite dielectric in a multi dielectric stack type spacer, capacitor, transistor or anti-fuse application. A dielectric layer can be used to form a continuous low temperature barrier layer. A dielectric layer can be used for low temperature conditioning for advanced dielectrics such as Ta₂O₅ and BST. A dielectric layer can be used for a low temperature post metal barrier layer or interconnect conditioning to reduce oxidation.

For the purposes of describing and defining the present invention, formation of a material “on” a substrate or layer refers to formation in contact with a surface of the substrate or layer. Formation “over” a substrate or layer refers to formation above or in contact with a surface of the substrate. Formation “in” a substrate or layer refers to formation of at least a portion of a structure in the interior of a substrate or layer. An “ultra-thin film” is a dielectric layer with a thickness not greater than 10 microns and uniformity within 20% of it's average value (Inventor: Please verify definition).

Having described the present invention in detail and by reference to preferred embodiments thereof, it will be apparent that modifications and variations are possible without departing from the scope of the present invention defined in the appended claims.

What is claimed is:

1. A method of forming an ultra thin dielectric film on a semiconductor device comprising:
providing a substrate having at least one semiconductor layer;
fabricating the semiconductor device proximate to the substrate;
forming an oxide layer over the semiconductor device;
depositing a silicon-containing material over at least a portion of the oxide layer from a silicon source; and
converting the oxide layer and deposited silicon-containing material into the ultra thin dielectric film by processing the deposited silicon-containing material and the oxide layer in a high density plasma.

2. The method of claim 1, wherein depositing a silicon-containing material over at least a portion of the oxide layer from a silicon source comprises depositing a silicon-containing material over at least a portion of the oxide layer from a silazane source.

3. The method of claim 1, wherein the silicon source is comprised of at least one material from the group comprising hexamethyldisilazane, tetramethyldisilazane, octamethylcyclotetrasilazine, hexamethylcyclotrisilazine, diethylaminotrimethylsilane and dimethylaminotrimethylsilane.

4. The method of claim 1, wherein depositing a silicon-containing material over at least a portion of the oxide layer from a silicon source comprises depositing a silicon-containing material over at least a portion of the oxide layer from a silane source.

5. The method of claim 1, wherein the high density plasma contains a material selected from the group comprising NH₃, N₂, and N₂+H₂.

6. The method of claim 1, wherein the ultra thin dielectric film is primarily nitride.

7. The method of claim 1, wherein the ultra thin dielectric film is primarily oxide.

8. The method of claim 1, wherein the ultra thin dielectric film is less than 30 Å in thickness.

9. A method of forming an ultra thin dielectric film on a semiconductor device comprising:
providing a substrate having at least one semiconductor layer;
fabricating the semiconductor device proximate to the substrate;
forming an oxide layer over the semiconductor device;
depositing a silicon-containing material over at least a portion of the oxide layer; and
converting the oxide layer and deposited silicon-containing material into the ultra thin dielectric film by positioning said substrate in a processing chamber, exposing plasma source gases to a high density plasma outside of the chamber to create activated species, and pumping the activated species into the processing chamber.

10. A method of forming a dielectric layer on a semiconductor device comprising:
providing a substrate having at least one semiconductor layer;
fabricating the semiconductor device over the substrate;
forming an oxide layer over at least a portion of the semiconductor device;
vapor depositing a silicon-containing material from a silazane source over at least a portion of the semiconductor device; and
converting the deposited silicon-containing material and the oxide layer into the dielectric layer by utilizing a high density plasma.

11. The method of claim 10, wherein the high density plasma is generated so as to avoid contact with the semiconductor device.

12. The method of claim 10, wherein the high density plasma density plasma is generated proximate the semiconductor device.

13. A method of forming a dielectric layer comprising:
providing a silicon substrate having at least one semiconductor layer;
forming an oxide layer over at least a portion of the silicon substrate;
vapor depositing a silicon-containing material from a silazane source over at least a portion of the oxide layer; and
converting the deposited silicon-containing material and the oxide layer into the dielectric layer by processing the silicon-containing material in a high density plasma at a processing temperature, a processing time and a processing pressure.

14. The method of claim 13, wherein the processing temperature, the processing time and the processing pressure are selected to result in a desired dielectric constant.

15. A method of fabricating a semiconductor device comprising:
providing a substrate having at least one semiconductor layer;
forming a gate oxide over at least a portion of the substrate;
depositing a silicon-containing material over the substrate from a silicon source; and
forming an electrode over at least a portion of the substrate by converting the gate oxide and deposited silicon-containing material to an oxynitride by flowing a selected material in a high density plasma.

16. The method of claim 15, wherein the selected material is NH₃.

17. The method of claim 15, wherein the silicon source material is hexamethyldisilazane.

18. A method of fabricating a semiconductor device comprising:
providing a substrate having at least one semiconductor layer;
depositing a thin gate oxide layer over at least a portion of the substrate;
vapor depositing silicon from hexamethyldisilazane over the thin gate oxide layer; and
subjecting the deposited silicon and the thin gate oxide layer to activated species from a remote high density plasma source so as to convert the deposited silicon and the thin gate oxide layer into an oxynitride layer.

19. The method of claim 18 further comprising:
forming a gate electrode over the oxynitride layer.

20. The method of claim 19 further comprising:
doping the gate electrode with phosphor.

21. The method of claim 19 further comprising:
doping the gate electrode with boron or arsenic.

22. The method of claim 18 wherein the high density plasma contains at least one material selected from the group comprising NH₃, N₂, O₂, O₃, N₂O and NO.

23. A method of fabricating a semiconductor device comprising:
providing a substrate having at least one semiconductor layer;
depositing a thin gate oxide layer over at least a portion of the substrate;
vapor depositing a silicon-containing material from tetramethyldisilazane over the thin gate oxide layer; and
subjecting the silicon-containing material and the thin gate oxide layer to a high density plasma resulting in converting the silicon-containing material and the thin gate oxide layers into an oxynitride layer.

24. A method of fabricating a semiconductor device comprising:
providing a substrate having at least one semiconductor layer;
depositing a thin gate oxide layer over at least a portion of the substrate;
vapor depositing silicon from a octamethylcyclotetrasilazine source over the thin gate oxide layer; and
subjecting the deposited silicon and the thin gate oxide layer to a high density plasma resulting in converting the deposited silicon and the thin gate oxide layers int a nitride layer.

25. A method for fabricating a semiconductor device comprising:
providing a substrate having at least one semiconductor layer;
forming a lower electrode over the substrate;
forming a native oxide over the lower electrode; and
depositing a silicon-containing material over at least a portion of the native oxide; and
converting the native oxide and the silicon-containing material into an oxynitride by flowing NH₃ in a high density plasma.

26. A method for fabricating a semiconductor device comprising:
providing a substrate having at least one semiconductor layer;
forming a lower electrode over at least a portion of the substrate and thereby forming a native oxide over the lower electrode;
depositing a silicon-containing material over the native oxide; and
converting the native oxide and the silicon-containing material into an oxynitride by flowing N₂+H₂ in a high density plasma.

27. A method of forming a dielectric layer on a semiconductor device comprising:
providing a substrate having at least one semiconductor layer;
forming an oxide layer over the substrate;
vapor depositing a silicon-containing material from a silazane source over at least a portion of the semiconductor device at a temperature of less than 300° C.; and
converting the deposited silicon-containing material and the oxide layer into the dielectric layer by utilizing a high density plasma at a temperature of less than 300° C.

28. A method of forming a dielectric layer on a semiconductor device comprising:
providing a substrate having at least one semiconductor layer;
forming an oxide layer over at least a portion of the substrate;
depositing a silicon-containing material from a silazane source over the oxide layer at a temperature of less than 300° C.;
converting the deposited silicon-containing material and the oxide layer into the dielectric layer by utilizing a high density plasma at a temperature of less than 300° C.; and
forming at least one additional dielectric layer over at least a portion of the dielectric layer.

29. A method of forming an ultra thin dielectric film on a semiconductor device comprising:
providing a substrate having at least one semiconductor layer;
fabricating the semiconductor device proximate to the substrate;
forming an oxide layer over the semiconductor device;
depositing a silicon-containing material over at least a portion of the oxide layer; and
converting the oxide layer and deposited silicon-containing material into ultra thin oxynitride dielectric film by exposing the substrate to activated species generated from a high density plasma source, wherein the ultra thin dielectric film is on the order of 30 Å in thickness or less.

30. A method for fabricating a semiconductor device comprising:
providing a substrate having at least one semiconductor layer;
cleaning the substrate by using hydrofluoric acid;
vapor depositing a silicon layer from hexamethyldisilazane over at least a portion of a surface of the wafer;
forming a silicon-containing dielectric layer by flowing NH3 in a high density plasma over the silicon layer;
forming a second dielectric layer over the silicon-containing dielectric layer; and
forming an electrode over the second dielectric layer.

31. A method for fabricating a semiconductor device comprising:
providing a substrate having at least one semiconductor layer;
cleaning the substrate by using hydrofluoric acid;
vapor depositing silicon-containing material from hexamethyldisilazane over at least a portion of a surface of the wafer at a low temperature such that the deposited silicon-containing material has a thickness of less than 20 Å;
forming a silicon-containing dielectric layer by flowing a high density plasma over the deposited silicon-containing material at the low temperature;
forming a second dielectric layer over the silicon-containing dielectric layer by low pressure chemical vapor depositing silicon nitride; and
forming a metal electrode over the second dielectric layer.

32. The method of claim 31, wherein the low temperature is less than 300° C.

33. A semiconductor device comprising:
a substrate having at least one semiconductor layer;
a first conductive layer formed over the substrate;
a silicon-containing dielectric layer formed over the first conductive layer at a low temperature;
a second dielectric layer formed over the silicon-containing dielectric layer; and
a second conductive layer formed over the second dielectric layer.

34. The semiconductor device of claim 33, wherein the second dielectric layer is comprised of a material selected from the group comprising Si₃N₄, BST, and PZT.

35. The semiconductor device of claim 33, wherein the second dielectric layer is comprised of a material selected from the group consisting of Si₃N₄, BST, PZT, Al₂O₃ and WOₓ.

36. A semiconductor device comprising:
a substrate having at least one semiconductor layer;
an electrode formed over at least a portion of the substrate and having a native oxide formed on the electrode;
a silicon-containing ultra thin dielectric film formed over the electrode from deposited silicon-containing material and a native oxide of the electrode; and
a second dielectric layer formed over the silicon-containing ultra thin dielectric film.

37. The semiconductor device of claim 36, wherein the electrode is comprised of a material selected from the group comprising P-Si, SiGe and metal.

38. The semiconductor device of claim 36, wherein the second dielectric layer is comprised of Ta₂O_{5.}

39. A semiconductor device comprising:
a substrate having at least one semiconductor layer; and
an ultra thin dielectric film formed over the substrate by converting vapor deposited silicon-containing material from a silicon source and a thin oxide layer using a high density plasma to cause silicon atoms from the deposited silicon-containing material and oxygen atoms of the thin oxide layer to react with ions of the high density plasma.

40. A semiconductor device comprising:
a substrate having at least one semiconductor layer; and
an ultra thin dielectric film formed over the substrate by converting vapor deposited silicon-containing material from hexamethyldisilazane and a thin oxide layer using a high density plasma.

41. A semiconductor device comprising:
a substrate; and
a oxynitrided gate formed over the substrate by converting vapor deposited material from a hexamethyldisilazane source and a gate oxide layer into the oxynitrided gate by flowing an NH₃ plasma over the deposited material.

42. A computer system comprising:
at least one processor;
a system bus; and
a memory device coupled to the system bus, the memory device including one or more memory cells comprising:
a substrate having at least one semiconductor layer;
a drain formed in the substrate;
a source formed in the substrate;
a first oxide layer deposited over the substrate stretching from the drain to the source rail;
a silicon-containing ultra thin dielectric film formed over the substrate from silicon-containing material deposited over the substrate and the first oxide layer; and
a gate electrode deposited over the ultra thin dielectric film.
